(19) United States
(12) Patent Application Publication
(10) Pub. No.: US 2007/0152761 A1
(43) Pub. Date: Jul. 5, 2007

(54) Voltage controlled oscillator with variable control sensitivity

(75) Inventors: Kwang Young Kim, Irvine, CA (US); Chun-Ying Chen, Irvine, CA (US); Mark Chambers, Mission Viejo, CA (US)

Correspondence Address: STERNE, KESSLER, GOLDSTEIN & FOX P.L.L.C., 1100 NEW YORK AVENUE, N.W., WASHINGTON, DC, 20005, US

(73) Assignee: Broadcom Corporation

(21) Appl. No.: 11/636,977

(22) Filed: Dec. 12, 2006

Related U.S. Application Data
(60) Provisional application No. 60/749,609, filed on Dec. 13, 2005.

(51) Int. Cl. H03L 7/00

(52) U.S. Cl. 331/16

(57) ABSTRACT

An embodiment of the invention provides an apparatus and method for varying a voltage controlled oscillator (VCO) sensitivity. A VCO has an oscillator portion coupled to a variable current supply. The variable current supply has one or more enabled variable current cells. The enable variable current cell input provides a control to change the VCO sensitivity. In an example, the oscillator portion has a ring oscillator. In an example, the variable current supply has at least two variable current cells that supply the control current. A binary control signal alters a quantity of variable current cells that supply the control current. Each successive variable current cell has an output current substantially equal to twice that of a prior variable current cell.

### CROSS REFERENCE TO RELATED APPLICATIONS

This application claims benefit of U.S. Provisional Patent No. 60/749,609 filed Dec. 13, 2005, which is incorporated by reference herein in its entirety.

### FIELD OF THE INVENTION

The present invention is generally directed to a voltage controlled oscillator (VCO). More particularly, the invention relates to an apparatus and method for varying VCO sensitivity.

### BACKGROUND OF THE INVENTION

Typical methods to increase phase-locked loop (PLL) frequency have detrimental effects of coupling power supply noise and decreasing PLL bandwidth. A PLL requires a finite period of time to process an input signal change, thus the PLL has limits on PLL frequency and PLL bandwidth. The following equation determines PLL frequency:
PLL frequency=Reference frequency·N_{DIV}
A crystal typically provides the reference frequency. Thus, the reference frequency is typically fixed. However, N_{DIV} is a feedback division factor that is variable. Therefore, N_{DIV} can be increased to increase the PLL frequency.

Unfortunately, increasing N_{DIV} has a detrimental effect of reducing PLL bandwidth. The following equation determines PLL bandwidth:
PLL bandwidth=I_{qp}·R_{zero}·K_{vco}/N_{DIV}
Where:
I_{qp}=Charge pump current
R_{zero}=Loop filter resistance
K_{vco}=VCO sensitivity to the control voltage={Δ VCO output frequency/Δ control voltage (Vc)}
   The PLL bandwidth must be high enough to follow a change in an input signal, but low enough to reject a signal error in the input signal. Furthermore, a constant PLL bandwidth is required for PLL stability. However, PLL bandwidth decreases when N_{DIV} is increased. Thus, when N_{DIV} is increased, PLL bandwidth must be restored. Alternatively, the PLL bandwidth reduction must be minimized.

Various methods exist to vary the PLL bandwidth. Two methods typically used to increase PLL bandwidth are increasing charge pump current and increasing loop filter resistance. However, increasing charge pump current causes a problem of reducing PLL headroom. Further, increasing loop filter resistance by switching in and out resistors to change a total resistance causes a problem of coupling supply noise through a switch to a PLL output signal.

What is needed is an apparatus and method to increase PLL frequency that has a minimal effect on affect PLL loop bandwidth and minimizes supply noise coupling as well as overcoming other shortcomings noted above.

### BRIEF SUMMARY OF THE INVENTION

An embodiment of the invention provides an apparatus and method for varying a voltage controlled oscillator (VCO) sensitivity. A variable current supply coupled to the VCO supplies a controlled current to an oscillator portion. Variable current sources vary the VCO sensitivity. One or more variable current sources controlled by a control voltage (Vc) are coupled to the oscillator portion. In an example, the oscillator portion has a ring oscillator.

The total current (Ic) from variable current sources determine the frequency of the oscillator. The VCO sensitivity (KVCO) is proportional to the quantity of variable current sources.

In an example, a variable-sensitivity VCO is part of a phase-locked loop (PLL). When PLL frequency is raised by changing a feedback division factor (N_{DIV}), VCO sensitivity is also adjusted substantially proportional to the change in N_{DIV} to maintain PLL bandwidth substantially constant. Thus, PLL frequency is increased with a minimal effect on affect PLL loop bandwidth.

In an example, the ring oscillator includes delay cells. The delay cells produce an oscillatory signal at a delay cell output. A filter is coupled across the delay cell output to filter noise. This makes the variable-sensitivity VCO less sensitive to noise. Thus, the filter minimizes supply noise coupling, such as noise injected by the variable current source.

Further embodiments, features, and advantages of the present invention, as well as the structure and operation of the various embodiments of the present invention, are described in detail below with reference to the accompanying drawings.

### BRIEF DESCRIPTION OF THE DRAWINGS/FIGURES

The accompanying drawings, which are incorporated herein and form a part of the specification, illustrate the present invention and, together with the description, further serve to explain the principles of the invention and to enable a person skilled in the pertinent art to make and use the invention.

In the drawings:

FIG. 1 illustrates a block diagram of an exemplary phase-locked loop (PLL);

FIG. 2A illustrates a block diagram of an exemplary voltage controlled oscillator (VCO);

FIG. 2B illustrates a block diagram of another exemplary VCO;

FIG. 3 illustrates a block diagram of a ring oscillator according to an embodiment;

FIG. 4 illustrates an exemplary delay cell;

FIG. 5 illustrates a flowchart of an exemplary method for varying PLL frequency; and

FIG. 6 illustrates a flowchart of an exemplary method for varying VCO sensitivity.

The present invention will now be described with reference to the accompanying drawings. In the drawings, like reference numbers indicate identical or functionally similar elements. Additionally, the left-most digit(s) of a reference number identifies the drawing in which the reference number first appears.

### DETAILED DESCRIPTION OF THE INVENTION

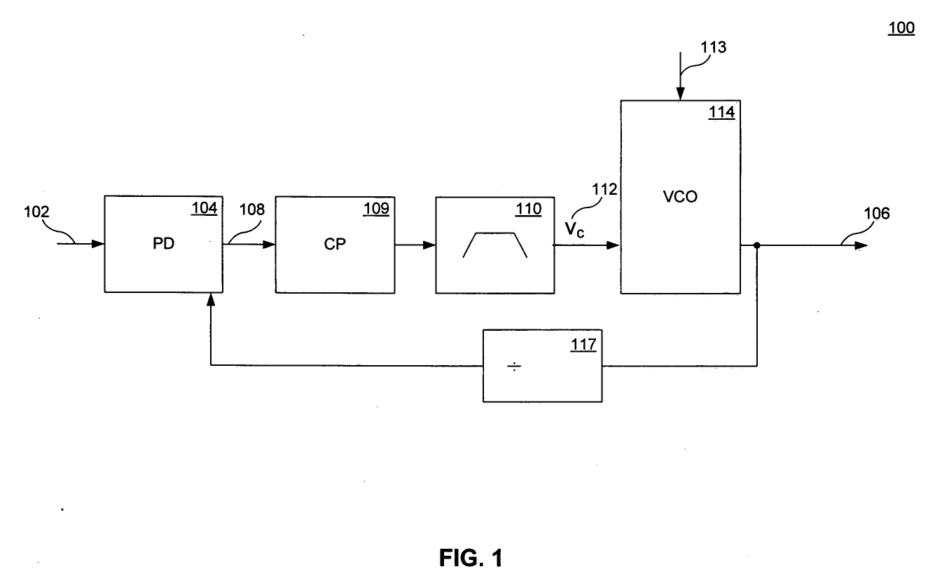

As introduced above, various embodiments of the invention involve an apparatus and/or method for varying a voltage controlled oscillator (VCO) sensitivity. FIGS. 1-6, described below, illustrate this approach.

This specification discloses one or more embodiments that incorporate the features of this invention. The disclosed embodiment(s) merely exemplify the invention. The scope of the invention is not limited to the disclosed embodiment(s). The invention is defined by the claims appended hereto.

The embodiment(s) described, and references in the specification to “one embodiment”, “an embodiment”, “an example embodiment”, etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

FIG. 1 illustrates a block diagram of an exemplary phase-locked loop (PLL) 100 having a variable-sensitivity VCO 114. An input 102 is coupled to a phase detector 104. A PLL output 106 is also coupled to the phase detector 104 via a frequency divider 117. The phase detector 104 is coupled to a charge pump 109 via a phase detector output 108. An output of the charge pump 109 is coupled to a loop filter 110. The loop filter 110 is coupled to a variable-sensitivity voltage controlled oscillator (VCO) 114. A control input 113 determines a number of variable current sources that are coupled to the variable-sensitivity VCO 114. The variable-sensitivity VCO 114 is coupled to the PLL output 106. In an example, the current supply control input 113 is a binary input.

A PLL input signal on the input 102 is applied to the phase detector 104. A PLL output signal from output 106 is also applied to the phase detector 104 via the frequency divider 117. The phase detector 104 determines a difference in phase between the PLL input signal and an output of the frequency divider 117 to determine a phase detector output 108. The charge pump 109 determines an unfiltered control voltage dependent on the phase detector output 108. The loop filter 110 filters the unfiltered control voltage to determine a control voltage (Vc) 112. The control voltage 112 is input to the variable-sensitivity VCO 114. The variable-sensitivity VCO 114 oscillates at a frequency that is dependent on the control voltage (Vc) 112 and a value of the control signal 113. The value of control signal 113 determines a number of active variable current sources. An output of the variable-sensitivity VCO 114 is the PLL output signal at output 106. The frequency divider 117 reduces a PLL output frequency by a feedback division factor (N_{DIV}) to a frequency substantially equal that of the PLL input signal to enable comparison.

The PLL 100 minimizes passing of signal errors, such as noise and frequency glitches, found in the input signal 102. The PLL 100 also locks the PLL output signal onto the PLL input signal by using feedback provided by the frequency divider 117. Thus, the PLL output signal frequency tracks changes in the PLL input signal frequency.

In an example, when the PLL frequency is changed by changing a feedback division factor (N_{DIV}), the sensitivity of variable-sensitivity VCO 114 is adjusted proportional to the change in N_{DIV} to maintain PLL bandwidth substantially constant. Thus, the PLL frequency is increased with minimal effect on PLL bandwidth. In an example, the control input 113 which determines the number of variable current sources is adjusted to increase VCO sensitivity (Kvco) which, in turn, increases PLL bandwidth.

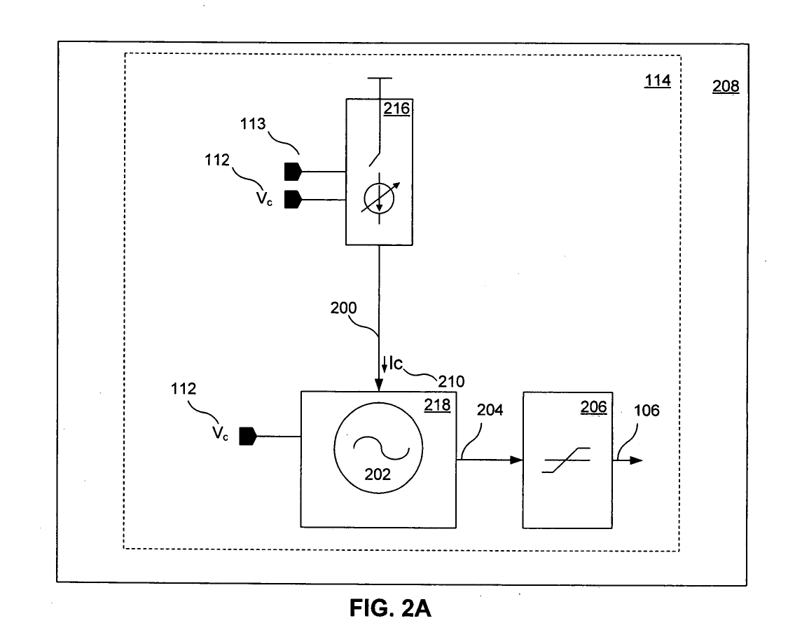

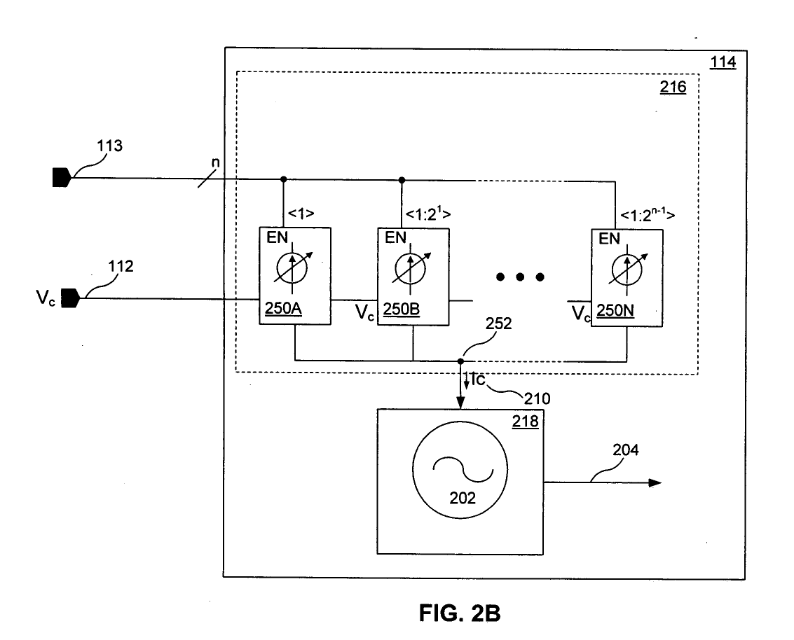

FIG. 2A illustrates an exemplary variable sensitivity VCO 114 with a variable current source 216. The variable current source 216 is coupled to an oscillator portion 218 via a variable current supply output 200. The control voltage 112 is coupled to the variable current source 216. The oscillator portion 218 is coupled to an oscillator output 204. In an example, the oscillator portion 218 has a ring oscillator 202, but other oscillators could be used. In an example, the oscillator output 204 is coupled to an optional zero crossing detector 206. A zero crossing detector output is the PLL output 106. When there is no zero crossing detector 206, the oscillator output 204 is coupled to the PLL output 106. In an example, the variable sensitivity VCO 114 is deposited on a substrate 208. In another example, at least one of the variable current source 216 and the oscillator portion 218 is deposited on the substrate 208.

The variable-sensitivity VCO 114 oscillates at a frequency that is determined by the control voltage 112. The control input 113 determines the number of variable current sources 216 to control a sensitivity of the variable-sensitivity VCO 114. The sum of the current of each control current (Ic) 210 is applied to the oscillator portion 218 via the variable current supply output 200. Varying the number of current sources according to the control input 113 varies the sensitivity of the variable sensitivity VCO 114. In an example, the PLL output signal is the oscillator output signal. In another example, the optional zero crossing detector 206 converts the oscillator output signal present at the oscillator output 204 from a sine wave to a square wave. An output of the zero crossing detector 206, and thus the variable-sensitivity VCO 114, is the PLL output signal present on the PLL output 106. In one embodiment, varying the number of enabled current sources varies the slope of the total current, which is applied to the VCO to change the VCO sensitivity.

FIG. 2B illustrates an example where the variable current source 216 has a plurality of current mirror cells 250A, B, . . . , N. Each current mirror cell 250 is controlled by the control input 113 which determines the number of variable current sources to be enabled. The output of each current mirror cell 250 is coupled to a common output node 252. The common output node 252 is coupled to the oscillator portion 218. In an example, at least one of the current mirror cells 250 is coupled to the cell enable control input via the current supply control input 113.

The current supply control input 113 controls each current mirror cell 250 to control the control current (Ic) 210 by enabling or disabling each individual current mirror cell 250. Thus, the control current (Ic) 210 is proportional to the value of the enable variable current cell input. In one embodiment, varying the number of enabled current mirror cells 250 varies the slope of the total current 210, which is applied to the oscillator portion 218 to change the VCO sensitivity.

In an example, the current supply control input 113 is a binary control. Each successive current mirror cell 250 has an output current substantially equal to twice that of a prior current mirror cell 250.

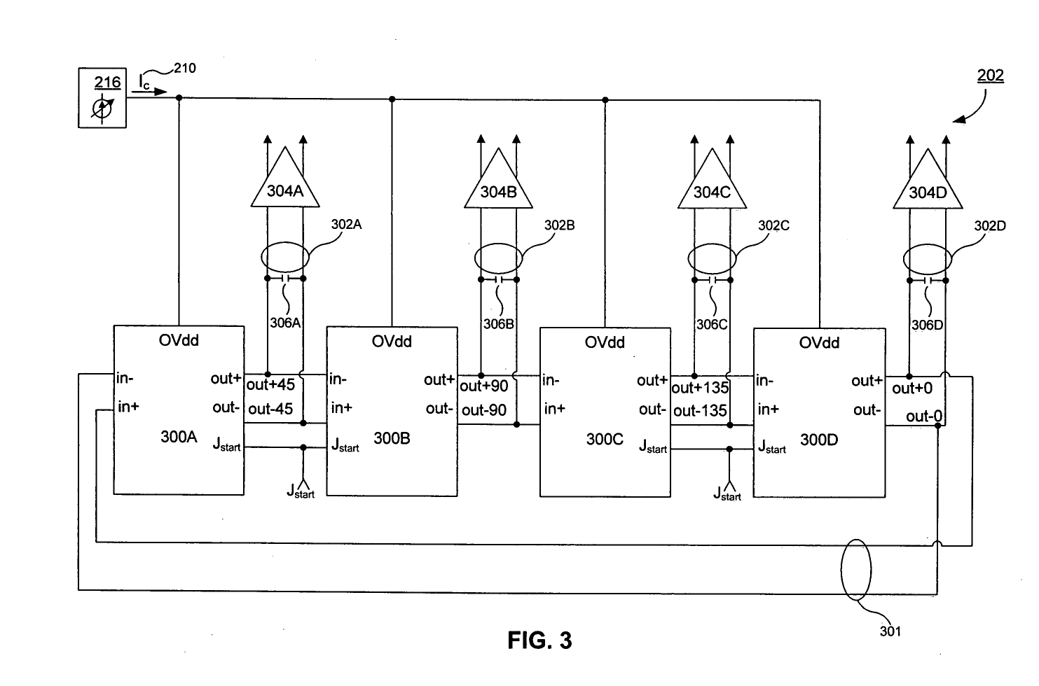

FIG. 3 illustrates an exemplary block diagram of the ring oscillator 202. The ring oscillator 202 has multiple delay cells 300A-D coupled in a ring with a transposed coupling 301. The ring oscillator 202 is not limited to four delay cells 300 as illustrated, but must have at least two delay cells 300. The delay cells 300 are coupled to the variable current source 216. The delay cells 300 have corresponding delay cell outputs 302A-D coupled to buffers 304A-D. An output of at least one of the buffers 304 is the oscillator output 204. A capacitor 306A-D is coupled across the delay cell output 302.

The delay cells 300 produce an oscillatory signal at the delay cell output 302. The capacitor 306 filters noise present at the delay cell output 302 to make the variable-sensitivity VCO 114 less sensitive to noise. Thus, the capacitor 306 minimizes noise, such as any supply noise injected by the variable current source 216. The buffer 304 buffers the delay cell output 302 to produce the oscillator output 204. In an example, the capacitor 306 filters noise occurring at frequency higher than the frequency of the oscillator output 204.

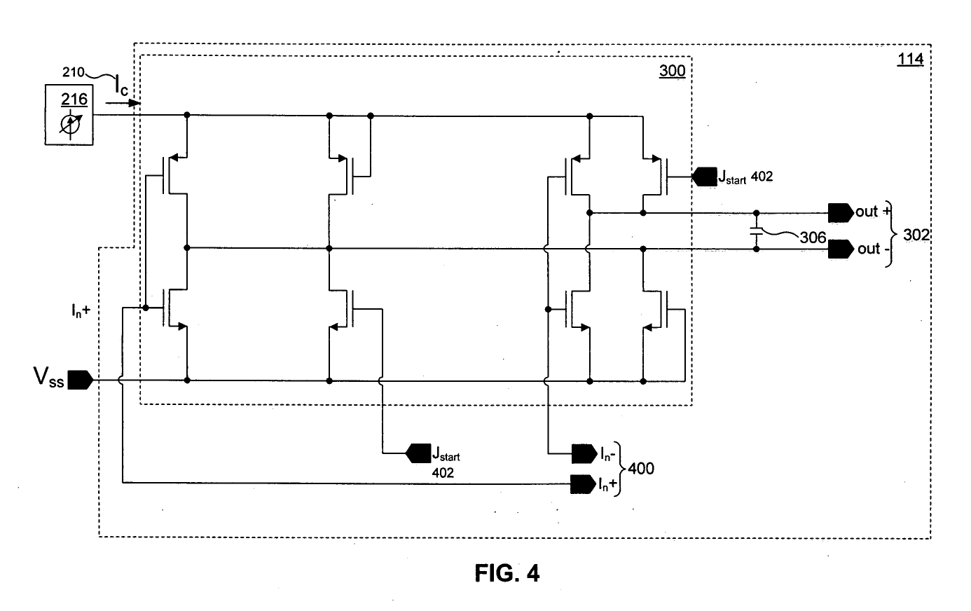

FIG. 4 illustrates an exemplary delay cell 300. The capacitor 306 is coupled across the delay cell output 302. The variable current source 216 is coupled to the delay cell 300 to provide the control current (Ic) 210. An optional jump start input (Jₛₜₐᵣₜ) 402 is also coupled to the delay cell 300. In an example, capacitor 306 is coupled across a delay cell input 400.

The capacitor 306 filters noise to make the delay cells 300, and thus the variable-sensitivity VCO 114, less sensitive to noise. The variable current source 216 varies the control current 210 to vary the sensitivity of the variable sensitivity VCO 114. The optional jump start input (Jₛₜₐᵣₜ) 402 starts oscillation in the delay cell 300.

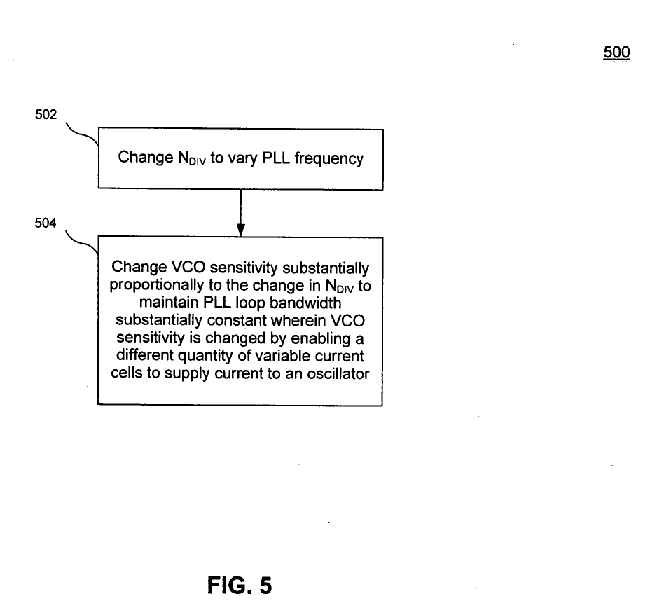

FIG. 5 illustrates a flowchart of an exemplary method for varying PLL frequency 500. In step 502, N_{DIV} is changed to vary PLL frequency. In step 504, the VCO sensitivity is changed substantially proportionally to the change in N_{DIV} to maintain PLL loop bandwidth substantially constant. The VCO sensitivity is changed by enabling a different number of variable current cells to supply current to an oscillator. In an example, the VCO sensitivity is changed by altering a quantity of variable current cells that supply the current to the VCO. In an example, a binary control signal is changed to alter the quantity of the current mirrors. In an example, noise is filtered from an output of at least one delay cell in the oscillator.

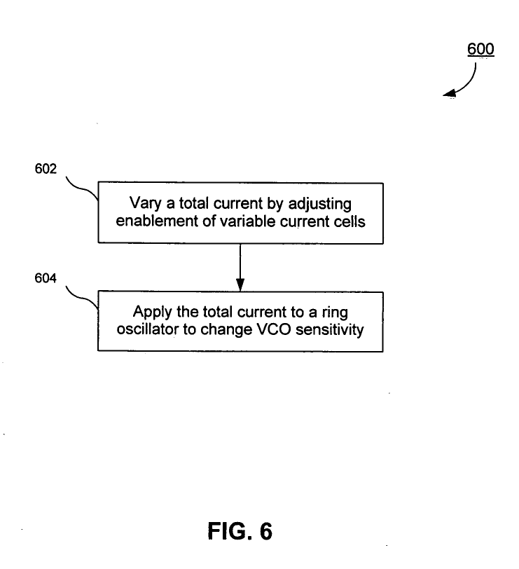

FIG. 6 illustrates a flowchart of an exemplary method for varying VCO sensitivity 600 in a VCO having a ring oscillator coupled to one or more variable current cells. In step 602, the variable current cell is adjusted to vary a current. In an example, a quantity of variable current cell circuits that supply the current is altered. In an example, a binary control signal is changed to vary the current. In an example, a binary control signal is changed to alter the quantity of variable current cell circuits that supply the current, which adjusts VCO sensitivity and thus PLL loop bandwidth.

In step 604, the current is applied to the ring oscillator to change VCO sensitivity. In an example, noise is filtered from an output of a delay cell in the ring oscillator.

It is to be appreciated that the Detailed Description section, and not the Summary and Abstract sections, is intended to be used to interpret the claims. The Summary and Abstract sections may set forth one or more but not all exemplary embodiments as contemplated by the inventor(s), and thus, are not intended to limit the present invention and the appended claims in any way.

What is claimed is:

1. A voltage controlled oscillator (VCO), comprising:
an oscillator portion; and
a variable current cell coupled to said oscillator portion, wherein said variable current cell has a current supply control input; and
wherein enablement of said current supply control input controls said variable current cell to change a VCO sensitivity of said VCO.

2. The VCO of claim 1, wherein said oscillator portion includes a ring oscillator.

3. The VCO of claim 2, wherein said ring oscillator includes:
a plurality of delay cells, wherein at least one delay cell has a differential output; and
a capacitor coupled across said differential output, wherein said capacitor rejects noise.

4. The VCO of claim 2, further comprising a VCO jump start input coupled to said ring oscillator.

5. The VCO of claim 1, wherein said VCO is part of a phase-locked loop.

6. The VCO of claim 5, wherein said VCO sensitivity is changed to vary a bandwidth of said phase locked loop.

7. The VCO of claim 1, further comprising a zero crossing detector coupled to an output of said oscillator portion.

8. The VCO of claim 1, further comprising at least one of said oscillator portion and said variable current cell deposited on a substrate.

9. The VCO of claim 1, wherein said variable current cell includes:
a current cell having an enable control input coupled to an input of a voltage controlled current source.

10. The VCO of claim 1, wherein said current supply control input is a binary control.

11. A method for varying a voltage controlled oscillator (VCO) sensitivity in a VCO having an oscillator portion coupled to variable current cells, comprising:
varying enablement of said variable current cells to alter a slope of a total current; and
applying said slope of said total current to said oscillator portion to change said VCO sensitivity.

12. The method of claim 11, further comprising filtering noise with a capacitor coupled across an output of a delay cell in said oscillator portion.

13. A voltage controlled oscillator (VCO), comprising:
means for varying a variable current supply to alter a current; and
means for applying said current to an oscillator portion to change a VCO sensitivity of said VCO.

14. The VCO of claim 13, wherein said means for varying further comprises means for altering a quantity of current mirror circuits that supply said current.

15. The VCO of claim 13, wherein said means for varying comprises means for changing a binary control signal to alter a quantity of current mirror circuits that supply said current.

16. The VCO of claim 13, further comprising means for filtering noise from an output of a delay cell in said oscillator portion.
